(19) United States
(12) Patent Application Publication
(10) Pub. No.: US 2009/0263946 A1
(43) Pub. Date: Oct. 22, 2009

(54) Device Having Pocketless Regions and Methods of Making the Device

(75) Inventors: Kamel Benaissa, Dallas, TX (US); Greg Baldwin, Plano, TX (US); Shashank Ekbote, Allen, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, DALLAS, TX (US)

(21) Appl. No.: 12/493,824

(22) Filed: Jun. 29, 2009

Related U.S. Application Data
(62) Division of application No. 11/668,946, filed on Jan. 30, 2007, now abandoned.

(51) Int. Cl. H01L 21/8238

(52) U.S. Cl. 438/231; 257/E21.634

(57) ABSTRACT

An example of the present application is directed to an integrated circuit having a first plurality of transistors and a second plurality of transistors. Each of the first plurality of transistors comprises a first gate structure oriented in a first direction and each of the second plurality of transistors comprises a second gate structure oriented in a second direction. Each of the first plurality of transistors are formed with at least one more pocket region than each of the second plurality of transistors. Methods for forming the integrated circuit devices of the present application are also disclosed.

### DESCRIPTION OF THE INVENTION

1. Field of the Invention

The present application is related to the field of integrated circuit devices, and more specifically to techniques for performing pocket (halo) implants during fabricating of integrated circuit devices.

2. Background of the Invention

CMOS design and fabrication involves the formation of transistors on a wafer. In the past, these transistors have been formed on the wafer to have differing directional orientations. As illustrated in FIG. 1, some transistors may be oriented similar to a transistor 1, where a gate 4 is oriented in one direction, while other transistors are oriented similar to a transistor 2, where a gate 8 is oriented in another direction. Illustrated regions 3 and 7 are active regions. In one example, a circuit may have as many as half the core logic transistors formed in one directional orientation, while the remaining core logic transistors are formed in the other direction.

As digital CMOS technology has extended into the deep submicron range (e.g., 0.35 micron and below), a transistor device feature was developed to enable a much shorter channel length. This particular feature is a pocket implant region, also known in the art as a halo implant region.

Generally, multiple pocket implants are performed during the fabrication of an integrated circuit. An example of a pocket implant process is illustrated in FIGS. 2A and 2B. As shown in FIG. 2A, a pocket implant 10a can be directed at an angle, α, which is less than perpendicular relative to the surface of the wafer, so that the resulting pocket region 16a extends adjacent to and under the gate structure 4, as is well known in the art. Thus, in order to form pocket implants on a wafer having transistors oriented in different directions, such as the transistors of FIG. 1, a first pocket implant 10a is performed at an angle, α, to form pocket region 16a adjacent to and under the gate structure 4 of transistor 1. Then, the wafer is rotated approximately 90 degrees, and a second pocket implant is carried out to form a pocket region (not shown) adjacent to and under the gate structure 8 of transistor 2, similarly as in the implant of FIG. 2A. The wafer is then rotated approximately another 90 degrees, and a third pocket implant 10b can be directed, also at an angle, α, to form a second pocket region 16b that extends adjacent to and under the opposite side of the gate structure 4. Finally, the wafer is rotated approximately another 90 degrees, and the wafer implanted a fourth time in order to form a pocket region on the opposite side of gate structure 8. In this manner, pocket regions are formed on each side of the gate structures 4 and 8 of FIG. 1.

Thus, because transistors are oriented in different directions on a wafer, generally four-pocket implant processes, (also referred to herein as four-rotation implants), are employed to form pocket regions for the transistors on a wafer, where the wafer is rotated 90 degrees between each rotation.

The pocket implants 10a and 10b, as shown in FIG. 2B, provide pocket regions 16a and 16b of heavier doping of the same conductivity type as the channel/body 18 of the CMOS transistor 20. Pocket regions 16a and 16b extend further under the gate than drain extension regions 24.

While MOSFETs designed with pocket implants are very attractive for high performance CMOS digital logic circuits, this is not the case for many CMOS analog circuits. The formation of pocket regions in some analog circuits has been known to undesirably cause poor channel conductance, poor matching, and increased flicker noise. Because there is a need in modern technologies to be able to build advanced circuitry of both a digital and analog nature on the same integrated circuit, methods have been developed for producing digital devices with pockets on the same wafer as analog devices that have no pockets.

One approach to suppressing the pocket in analog devices is to add a masking level for the pocket implant. In a conventional CMOS process, the drain extension or lightly doped drain (LDD) and the pocket implants are performed using the same mask for the low voltage transistors. An additional masking level can be added to suppress the pocket implant, where a pocket mask is used to block the analog transistors and only implant in the digital transistors. The problem with this approach is the cost of adding masking levels.

Thus, there is a need in modern technologies to be able to fabricate transistors that are more analog friendly along with digital transistors on the same wafer. Processes that can form both pocketless devices and devices with pockets on the same wafer in a cost effective manner are desired.

### SUMMARY

According to various embodiments, a method of forming an integrated circuit is provided. The method includes providing a first plurality of transistors, wherein each of the first plurality of transistors has a first active region and a first gate structure oriented in a first direction over the first active region. A second plurality of transistors is provided, wherein each of the second plurality of transistors has a second active region and a second gate structure oriented in a second direction over the second active region. One or more pocket implants are performed on both the first plurality of transistors and the second plurality of transistors, wherein the one or more pocket implants result in each of the first plurality of transistors being formed with at least one more pocket region than each of the second plurality of transistors.

According to various embodiments, another method of ion implanting to form integrated circuits is provided. The method includes providing first transistor devices having two pocket regions and second transistor devices having less than two pocket regions. The method further includes providing a wafer having a first plurality of transistors and a second plurality of transistors. Each of the first plurality of transistors has a first gate structure oriented in a first direction and each of the second plurality of transistors has a second gate structure oriented in a second direction. The wafer is inserted into an ion implanting apparatus and a pocket implant process is performed comprising at least two consecutive pocket implants on the wafer to form pocket regions. The wafer is then removed from the implanting apparatus. The method results in two pocket regions being formed adjacent and under opposing sides of all of the first gate structures, and no more than one pocket region being formed adjacent and under all of the second gate structures.

According to various embodiments, an integrated circuit having a first plurality of transistors and a second plurality of transistors is provided. Each of the first plurality of transistors includes a first gate structure oriented in a first direction and each of the second plurality of transistors comprises a second gate structure oriented in a second direction. Each of the first plurality of transistors are formed with at least one more pocket region than each of the second plurality of transistors.

According to various other embodiments, a transistor having no more than one pocket region is provided. The transistor includes an active region and a gate conductor over the active region. A channel region including a dopant of a first conductivity type in a first concentration is formed under the gate conductor. Drain extension regions of a second conductivity type extend adjacent and under the gate conductor. The transistor also includes at least one additional dopant region comprising a dopant of the first conductivity type in a second concentration that is greater than the first concentration. The at least one additional dopant region is adjacent to and aligned with the gate conductor, so that the additional dopant region does not substantially extend under the gate conductor.

Additional embodiments and advantages of the disclosure will be set forth in part in the description which follows, and can be learned by practice of the disclosure. It is to be understood that both the foregoing general description and the following detailed description are exemplary and explanatory only and are not restrictive of the disclosure, as claimed.

### BRIEF DESCRIPTION OF THE DRAWINGS

The accompanying drawings, which are incorporated in and constitute a part of this specification, illustrate embodiments of the invention and together with the description, serve to explain the principles of the invention. In the figures:

FIG. 1 illustrates an example of transistor devices having different directional orientations.

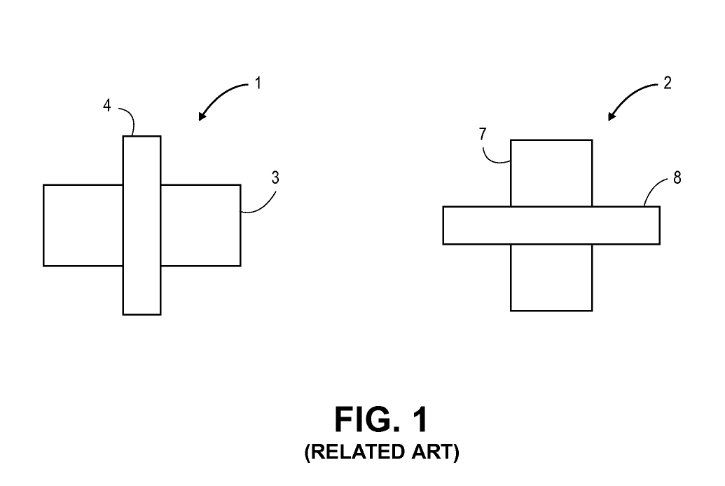

FIGS. 2A and 2B illustrate an example of a pocket implant process.

FIGS. 3A and 3B illustrate a top view of one embodiment in which transistors are doped using a two-rotation pocket implant process according to the present teachings.

FIG. 4 illustrates a cross section of the transistor shown in FIG. 3B, having a doping region formed during the pocket implant process according to the present teachings.

FIGS. 5A and 5B illustrate a top view of one embodiment in which transistors are doped using a three-rotation pocket implant process according to the present teachings.

### DESCRIPTION OF THE EMBODIMENTS

Reference will now be made in detail to the present embodiments (exemplary embodiments) of the invention, examples of which are illustrated in the accompanying drawings. Wherever possible, the same reference numbers will be used throughout the drawings to refer to the same or like parts.

Advanced CMOS design rules call for a single orientation gate process, where all or substantially all core logic transistors are oriented in the same direction. This is a substantially different paradigm shift in processing from conventional methods in which core logic transistors are fabricated having at least two different orientations on the wafer. As used herein “transistor orientation”, means that the longitudinal axis of the gate is oriented in a desired direction on the wafer.

Core logic transistors are generally digital transistors, which can benefit from pocket implants. In a process where core logic transistors are oriented in the same direction, two rotation pocket implants can be used to form pockets in all or substantially all of the core logic transistors. This provides an advantage over conventional process, which as described above, generally requires four-rotation pocket implant processes.

One advantage of forming the core logic transistors in a single orientation is that transistors without pockets can be formed by orienting these “pocketless” transistors in the opposite direction relative to the core transistors. The term “without pockets” is interchange with the term “pocketless,” as used herein, and means that the doped regions formed during the pocket implants do not extend substantially under the gate structures of the transistor in order to significantly shorten the channel length, as would occur in a typical pocket implant.

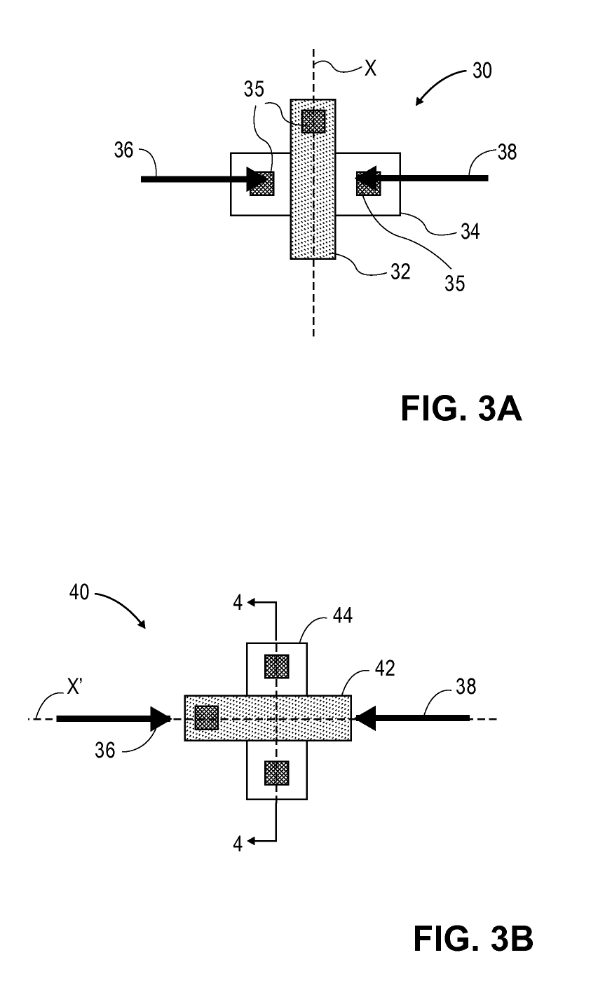

FIG. 3A illustrates a top view of one embodiment of the present teachings in which core transistors 30 are doped using only two-rotation pocket implants. Transistor 30 has a gate structure 32, contact regions 35, and an active region 34. As is well known in the art, the active region of a transistor can include, for example, drain extension regions, source and drain regions, and pocket regions. The gate structure 32 is oriented in a first direction so that the longitudinal axis x of gate structure 32 is substantially parallel with all or substantially all of the core logic transistors, as described above.

Pocket implants are performed, as illustrated by arrows 36 and 38. Pocket implants 36 and 38 can be carried out at any suitable point in the process, such as, for example, after the gate structure 32 has been formed, in order to provide for self-alignment of the pocket implants with the gate structure. In some embodiments, the pocket implants can occur after the gate etch, but prior to gate oxidation or formation of gate side spacers. In other embodiments, pocket implants can occur either after gate oxidation, or after both gate oxidation and formation of side spacers. Pocket implants for different devices are sometimes formed at different times in the process flow. In one exemplary embodiment for forming NMOS and PMOS devices with lightly doped drains (“LDD”), the pocket implants for the NMOS LDD devices can be carried out after gate etch and formation of a first set of gate side spacers; then the PMOS LDD devices can be carried out after an additional second set of gate side spacers are formed.

In one embodiment, pocket implants are carried out using the same mask that is used for forming LDD drain extensions. For example, the pocket implants can be performed after the drain extensions are formed, but prior to formation of the source and drain regions. In other embodiments, it may be desirable to perform the pocket implants prior to formation of the drain extensions.

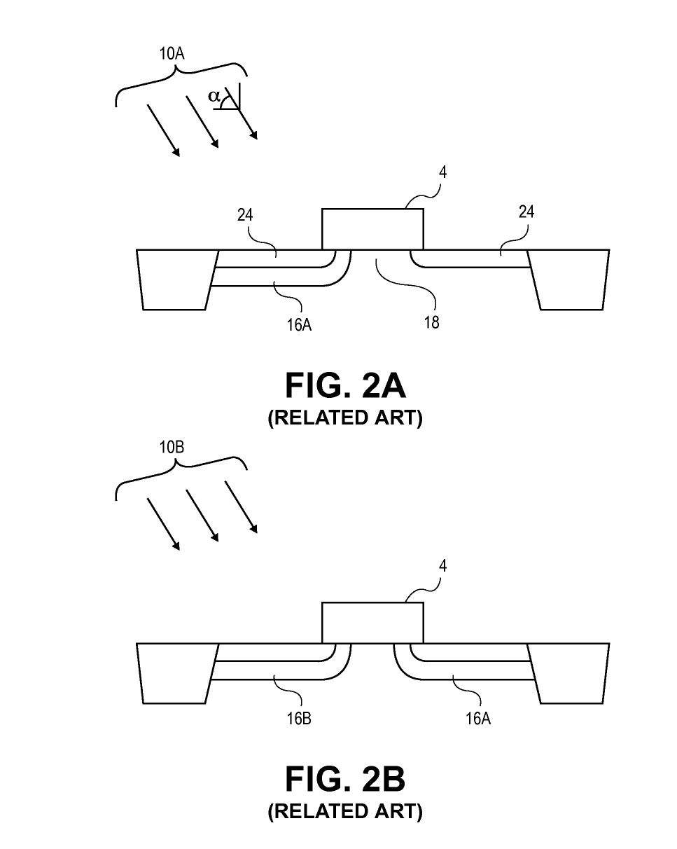

The arrows 36 and 38 illustrate the directional component of the pocket implants parallel to the substrate (termed herein as “horizontal” component). In actuality, the pocket implants are directed at the substrate at an angle, α, which is less than vertical (relative to the surface of the wafer), similarly as described above with respect to FIG. 2, so that the implants have both a horizontal component and a vertical component. As shown in FIG. 3A, the horizontal component of the pocket implant is substantially perpendicular to the longitudinal axis, x, of the gate structure. The angle and direction of the pocket implant results in a pocket region in the core transistors 30 that extends adjacent to and under the gate structure 32, similarly as shown in FIG. 2 above.

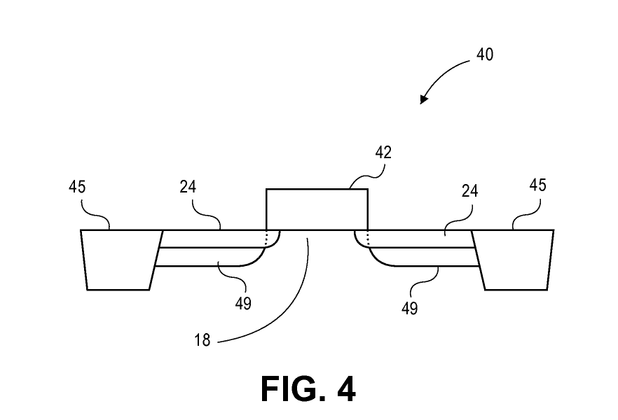

FIG. 3B illustrates one embodiment of a top view of a transistor 40, having a gate structure 42 and an active region 44, similar to transistor 30 of FIG. 3A, except that transistor 40 is oriented in a different direction relative to transistor 30. In one embodiment, gate structure 42 of transistor 40 is oriented in a second direction so that the longitudinal axis x′ of gate structure 42 is substantially perpendicular with the longitudinal axis x of the gate structure 32 in FIG. 3A. The orientation of transistor 40 relative to transistor 30 results in “pocketless” transistors being formed during the pocket implants 36 and 38, despite the fact that pocket implants 36 and 38 are carried out on the transistor 40 without additional masking to block the implants. This is because, as shown in FIG. 3B, the horizontal component of the pocket implants is parallel with the longitudinal axis x′ of the gate structure 42, resulting in a pocket implant doping profile that does not substantially extend underneath gate structure 42. FIG. 4 illustrates a cross section of transistor 40, showing a doping region 49 formed during the pocket implant. Doping region 49 is doped with the same dopant type as channel region 18. However, doping region 49 has a higher concentration of dopant. For example, where channel region 18 is formed with a p-type dopant, doping region 49 has a relatively higher concentration of p-type dopant. Because the profile of doping region 49 does not substantially extend underneath the gate, it does not effectively shorten the length of channel region 18 of the transistor, as in the case of the pocket regions formed for transistor 30, and thus is not a “pocket region” as defined herein. In the embodiment of FIG. 4, regions 24 are drain extension regions, and 45 are isolation regions, such as a shallow trench isolation or LOCOS region. Drain extension regions 24 are doped with a dopant of the opposite type as channel region 18. For example, where channel region 18 is formed with a p-type dopant, drain extensions regions 24 are doped with an n-type dopant, and vice-versa.

Transistor 40 is formed “pocketless” due to its orientation relative to the direction of the two-rotation pocket implants 36 and 38, as discussed above, without adding any additional masking steps to block the pocket implants. Thus, by orienting devices that benefit from being formed pocketless differently from devices that are formed with pockets, a process is provided that forms both types of devices with relatively little cost compared with conventional processing.

The pocket implants 36 and 38 are carried out in an ion implanting apparatus. Suitable ion implanting apparatuses are well known in the art. The process involves inserting a wafer comprising a plurality of transistors 30, oriented in a first direction, and a plurality of transistors 40, oriented in another direction, into the ion implanting apparatus. An implanting process comprising one or more pocket implants is then carried out. In some embodiments, at least two consecutive pocket implants are performed on the wafer to form pocket regions, prior to removing the wafer from the ion implanting device. The wafer is rotated between each rotation in order to implant at the desired angle relative to the gate structures, as described above. For example, in a two-implant process, a first pocket implant 36, as shown in FIGS. 3A and 3B, can be carried to form a first pocket region in transistor 30. The pocket implant can be directed at an angle, α, which is less than perpendicular relative to the surface of the wafer, as described above, so that the resulting pocket region extends adjacent to and under the gate structure. Then the wafer is rotated approximately 180° , and a second pocket implant is carried out, also at an angle, α, to form a pocket region on the opposing side

In other embodiments, a single implant process or a three-implant process can be carried out in the ion implanting apparatus. These processes result in formation of asymmetrical devices, as will be described in greater detail below. In some embodiments, a pocket implanting sequence can comprise one or more pocket implants performed consecutively in the same ion implanting apparatus. The phrase “pocket implanting sequence” is defined herein to mean the entire pocket implanting process that occurs to form the pocket regions as they will exist in any given completed transistor device or plurality of devices.

After the desired number of pocket implants are carried out, the wafer is removed from the ion implanting apparatus. Further processing can then be performed on the wafer, as is well known in the art. For example, sidewall spacers may be formed, followed by the n-type and p-type source/drain regions. Fabrication may then continue with a standard metal backend process.

Transistor 30 can be any device that would benefit from being formed with two pocket regions. Examples of such devices include both analog and digital transistors, including but not limited to low voltage transistors, high voltage transistors, low cost input/output transistors and high performance input/output transistors, as well as some analog devices. In an embodiment, transistor 30 is a digital device, such as a core logic device. In some embodiments, over 75% of the transistor devices in the integrated circuit are digital devices that are oriented in the same direction so as to be formed with two pocket regions. For example, 80% to 90% of the transistor devices in the integrated circuit can be digital devices that are oriented in the same direction.

Transistor 40 can be any device that would benefit from being formed without pocket regions, including but not limited to both analog and digital devices. Such devices can include, for example, low voltage transistors, high voltage transistors, low cost input/output transistors and high performance input/output transistors, which may be oriented differently from the transistors 30, so as to be formed without pocket regions. In one embodiment, transistor 40 is an analog device.

As is well known in the art, a single integrated circuit formed on a wafer can include several different types of transistors. The pocket regions for these different transistors can be formed at different times during the process flow. Thus, a different pocket implant processes can be used to form pocket regions for low voltage transistors than is used to form pocket regions for high performance input/output devices on the same integrated circuit. For example, in embodiments of the present application, a two pocket implant process can be carried out to form pocket regions for low voltage transistors and low cost input/output transistors; and a separate two pocket implant process can be carried out to form pocket regions for high performance input/output transistors.

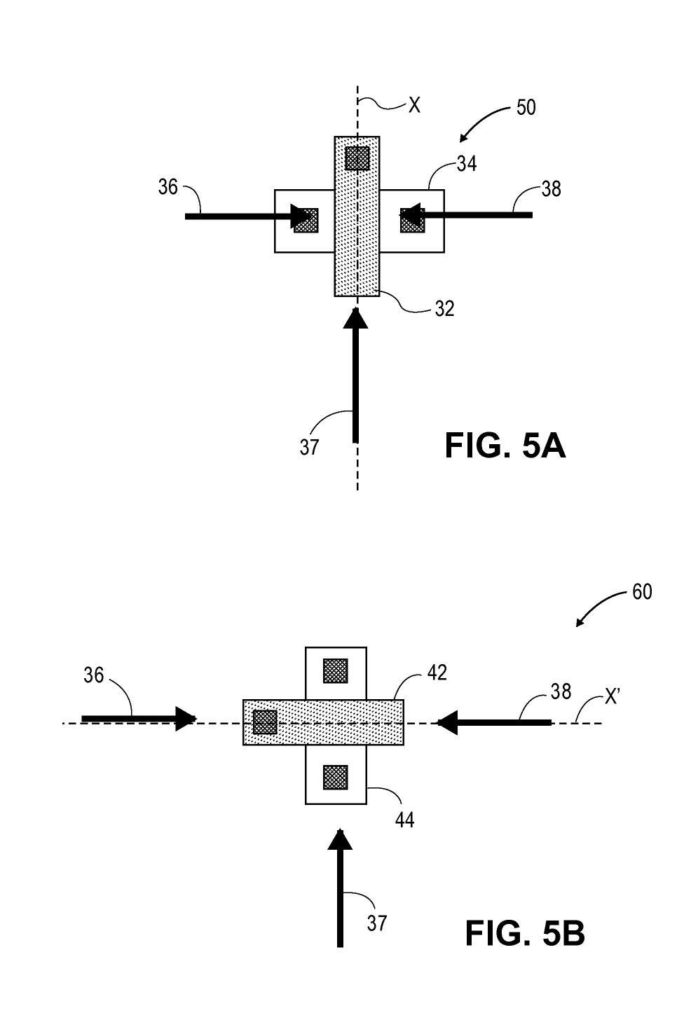

Another embodiment of the present application is illustrated in FIGS. 5A and 5B, which is similar to the embodiment of FIGS. 3A and 3B above, except that three pocket implant rotations, 36, 37 and 38, are employed instead of only two. The three-rotation process allows the formation of an asymmetric device, as shown in FIG. 5B, which has a pocket region adjacent and under only one side of the gate structure 42. Similarly as described above, employing a device layout design in which transistors to be formed with two pocket regions are formed in the same directional orientation, and asymmetric devices are formed having a different directional orientation relative to the orientation of the two-pocket transistors, allows the formation of the asymmetric devises without the use of additional masking steps.

As used herein the term “asymmetric transistor” means a transistor having only one pocket region. Asymmetric devices are well known in the art. Examples of asymmetric devices are disclosed in U.S. Pat. No. 6,413,824, issued Jul. 2, 2002, to Chatterjee, the disclosure of which is hereby incorporated by reference in its entirety.

In the embodiment of FIG. 5A, a transistor 50 has a gate structure 32 and an active region 34, similarly as described above in the embodiment of FIG. 3A. The gate structure 32 is oriented in a first direction so that the longitudinal axis x of gate structure 32 is substantially parallel with all or substantially all of the core logic transistors.

Pocket implants are formed, as illustrated by arrows 36, 37 and 38. As shown in FIG. 5A, the horizontal component of pocket implants 36 and 38 is substantially perpendicular to the longitudinal axis x of gate structure 32. The angle and direction of the pocket implant results in a pocket region in the core transistors 50 that extends adjacent to and under the gate structure 32. The horizontal component of the third implant 37 is in a direction that is substantially parallel with the x axis, and therefore results in a dopant region that does not extend substantially under the gate structure 32 in the active region 34.

FIG. 5B illustrates one embodiment of a top view of a transistor 60, having a gate structure 42 and an active region 44, similar to transistor 50 of FIG. 5A, except that transistor 60 is oriented in a different direction relative to transistor 50. In one embodiment, gate structure 42 of transistor 60 is oriented in a second direction so that the longitudinal axis x′ of gate structure 42 is substantially perpendicular with the axis x of the gate structure 32 of transistor 30. This orientation allows an asymmetric transistor to be formed, despite the fact that the pocket implants 36 and 38 are also carried out on the transistor 60 without additional masking to block the implants. This is because, as shown in FIG. 5B, the horizontal components of pocket implants 36 and 38 are parallel with the longitudinal axis x′ of the gate structure 42, resulting in a pocket implant doping profile that does not substantially extend underneath gate structure 42.

However, the horizontal component of pocket implant 37 is substantially perpendicular to the longitudinal axis x′ of gate structure 42. This results in pocket implant 37 forming a pocket region in the transistor 60 that extends adjacent to and under one side of the gate structure 32. The pocket can be formed in either the source side or the drain side of the device. In one embodiment, the pocket region is formed on the drain side of transistor 60. In another embodiment, the pocket region is formed on the source side of transistor 60.

In this manner, transistor 60 is formed to be “asymmetric” due to its orientation relative to the direction of the three rotation pocket implants, as discussed above, without adding any additional masking steps to block the pocket implants. Thus, by orienting devices that benefit from being formed asymmetrically differently from devices that are formed with pockets, a process is provided that forms both types of devices with relatively little cost compared with conventional processing.

Transistor 50 can be any device that would benefit form being formed with pocket regions. Examples of such devices include both analog and digital transistors, including but not limited to low voltage transistors, high voltage transistors, low cost input/output transistors and high performance input/output transistors, as well as some analog devices. In an embodiment, transistor 50 is a digital device, such as a core logic device. In some embodiments, over 75% of the transistor devices in the integrated circuit are digital devices that are oriented in the same direction so as to be formed with two pocket regions. For example, 80% to 90% of the transistor devices in the integrated circuit can be digital devices that are oriented in the same direction.

Transistors 60 can be any device that would benefit from being formed with only one pocket region, including analog devices and digital devices. Suitable examples of such devices include both analog and digital. Such devices can include but are not limited to, for example, low voltage transistors, high voltage transistors, low cost input/output transistors and high performance input/output transistors, which may be oriented differently from the transistors 50, so as to be formed without pocket regions. In one embodiment, device 50 is a digital transistor and device 60 is an analog transistor.

In yet another embodiment, the methods of the present application can be employed to make an asymmetrical device using only a single implant. For example, this process can be similar to the process described above with respect to FIG. 3A, except that only a single implant 36 is performed, instead of both implants 36 and 38. This process would result in transistor 30 being formed as an asymmetrical device having only a single pocket region; while transistors oriented in the other direction, such as transistor 40 in FIG. 3B, would receive only a single implant 36, having a horizontal component that is parallel to the longitudinal axis x′ of gate structure 42. For reasons similar to those described above, this would result in transistor 40 being formed with no pocket regions.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

1. A method of forming an integrated circuit comprising:
providing a first plurality of transistors, wherein each of the first plurality of transistors has a first active region and a first gate structure oriented in a first direction over the first active region;
providing a second plurality of transistors, wherein each of the second plurality of transistors has a second active region and a second gate structure oriented in a second direction over the second active region;
performing one or more pocket implants on both the first plurality of transistors and the second plurality of transistors, wherein the one or more pocket implants result in each of the first plurality of transistors being formed with at least one more pocket region than each of the second plurality of transistors.

2. The method of claim 0, wherein at least two pocket implants are performed on both the first plurality of transistors and the second plurality of transistors, wherein one pocket region is formed adjacent and under each opposing side of all of the first gate structures, and wherein the pocket implants result in no more than one pocket region formed in each of the active regions adjacent and under all of the second gate structures.

3. The method of claim 0, wherein the plurality of first transistors are digital transistors.

4. The method of claim 0, wherein the plurality of second transistors comprise analog transistors.

5. The method of claim 0, wherein the plurality of second transistors comprise at least one device chosen from a low voltage transistor, high voltage transistor, low cost input/output transistor and high performance input/output transistor.

6. The method of claim 0, wherein no more than three pocket implants of the plurality of first transistors and the plurality of second transistors are performed.

7. The method of claim 0, wherein only two pocket implants of the plurality of first transistors and the plurality of second transistors are performed.

8. The method of claim 0, wherein a mask is not used to block the implantation of ions into the second active regions adjacent and under the second gate structures during the pocket implants.

9. A method of ion implanting to form integrated circuits comprising first transistor devices having two pocket regions and second transistor devices having less than two pocket regions, the method comprising:
providing a wafer having a first plurality of transistors and a second plurality of transistors, wherein each of the first plurality of transistors has a first gate structure oriented in a first direction and each of the second plurality of transistors has a second gate structure oriented in a second direction;
inserting the wafer into an ion implanting apparatus;
performing a pocket implant process comprising at least two consecutive pocket implants on the wafer to form pocket regions; and
removing the wafer from the implanting apparatus,
wherein one pocket region is formed adjacent and under each opposing side of all of the first gate structures, and wherein no more than one pocket region is formed adjacent and under all of the second gate structures.

10. The method of claim 0, wherein the pocket implant process comprises only two pocket implants.

11. The method of claim 0, wherein performing the two pocket implants comprises:
performing a first pocket implant;
rotating the wafer approximately 180°; and then performing a second pocket implant.

12. The method of claim 0, wherein the pocket implant process comprises only three pocket implants.

13. The method of claim 0, wherein no pocket regions are formed under the second gate structures.

14. The method of claim 0, wherein one pocket region is formed under the second gate structures.

15-25. (canceled)

26. A method of forming an integrated circuit comprising:
providing a first plurality of transistors, wherein each of the first plurality of transistors has a first active region and a first gate structure oriented in a first direction over the first active region;
providing a second plurality of transistors, wherein each of the second plurality of transistors has a second active region and a second gate structure oriented in a second direction over the second active region;
performing a pocket implanting sequence on both the first plurality of transistors and the second plurality of transistors, wherein the pocket implanting sequence results in each of the first plurality of transistors being formed with at least one more pocket region than each of the second plurality of transistors.

27. The method of claim 26, wherein the pocket implanting sequence comprises only a single pocket implant.

28. The method of claim 26, wherein the pocket implanting sequence comprises only two pocket implants.

29. The method of claim 26, wherein the pocket implanting sequence comprises only three pocket implants.
